(19) United States
(12) Patent Application Publication
(10) Pub. No.: US 2014/0191342 A1
(43) Pub. Date: Jul. 10, 2014

(54) MEMS SENSOR

(71) Applicants: Ichiro Ohsaka, Tokyo (JP); Kazunori Ohta, Hitachinaka (JP)

(72) Inventors: Ichiro Ohsaka, Tokyo (JP); Kazunori Ohta, Hitachinaka (JP)

(73) Assignee: Hitachi Automotive Systems, Ltd.

(21) Appl. No.: 14/239,877

(22) PCT Filed: Aug. 10, 2012
(86) PCT No.: PCT/JP2012/070420

§ 371 Date: Feb. 20, 2014

(30) Foreign Application Priority Data
Sep. 30, 2011 (JP) 2011-215901

(51) Int. Cl. B81B 3/00

(52) U.S. Cl. CPC B81B 3/0018
USPC 257/415

(57) ABSTRACT

There is provided a MEMS sensor including a signal processing LSI equipped with a temperature sensor for measuring temperature of a sensor, and a MEMS sensor chip overlaid on the signal processing LSI, the MEMS sensor chip being mounted on a heat generating part of the signal processing LSI. This MEMS sensor decreases the effects caused by thermally triggered changes in temperature characteristics.

### TECHNICAL FIELD

The present invention relates to the structure of a sensor. More particularly, the invention relates to the structure of a MEMS sensor that puts MEMS technology to practical use.

### BACKGROUND ART

MEMS (Micro Electro Mechanical Systems) technology that permits formation of mechanical structures on the semiconductor substrate is applied to diverse kinds of sensors and light application apparatuses.

Sensors created by application of MEMS technology (i.e., MEMS sensors) are manufactured using semiconductor processes. As such, MEMS sensors are often small in size and provide output signals of infinitesimally low output levels. Thus the MEMS sensor is generally equipped with a signal processing LSI at its subsequent stage.

Meanwhile, between the manufacturing process of MEMS sensors and that of semiconductors, there are few aspects of compatibility including deep RIE etching. Also different between them are the ways sacrifice layers are treated. Furthermore, juxtaposing a MEMS sensor chip and processing circuits can pose problems of taking up space. For this reason, the MEMS sensor chip and a signal processing LSI are often prepared as separate chips.

In such cases, the signal processing LSI is often overlaid on the MEMS sensor chip, as described in Patent Document 1 cited below.

### PRIOR ART DOCUMENTS

### Patent Document

Patent Document 1: JP-2009-53100-A

### SUMMARY OF THE INVENTION

### Problem to be Solved by the Invention

When overlaid one on the other as described in Patent Document 1, the MEMS sensor chip and the signal processing LSI chip are bonded together using such adhesive members as an adhesive agent or an adhesive sheet. Generally, the MEMS chip generates little heat; heat generation comes mostly from the signal processing LSI chip. The heat is therefore propagated to the MEMS chip via the adhesive member.

Also, if the MEMS chip and the signal processing LSI chip are bonded together in a manner randomly positioned to each other, the MEMS chip can develop a temperature gradient depending on where the heat generating part of the signal processing LSI is located. The temperature gradient on the MEMS chip translates into a temperature gradient in the sensing element, possibly resulting in thermally caused deterioration in performance.

Furthermore, the temperature gradient, if occurring in the MEMS sensor element, can make it difficult for a temperature sensor part in the sensor on the signal processing LSI to carry out temperature characteristic correction on the sensor itself.

An object of the present invention is to provide a MEMS sensor that reduces the effects caused by thermally triggered changes in temperature characteristics.

### Means for Solving the Problem

In achieving the above object, the present invention provides a MEMS sensor including a signal processing LSI equipped with a temperature sensor for measuring temperature of a sensor, and a MEMS sensor chip overlaid on the signal processing LSI, the MEMS sensor chip being mounted on a heat generating part of the signal processing LSI.

This patent application incorporates the content of the description and/or the drawings of Japanese Patent Application No. 2011-215901 to which this patent application claims priority.

### Effect of the Invention

The present invention provides a MEMS sensor that reduces the effects caused by thermally triggered changes in temperature characteristics.

### BRIEF DESCRIPTION OF THE DRAWINGS

FIG. 1 is a top view of a MEMS sensor as a first embodiment of the present invention.

FIGS. 2A and 2B are perspective views of the MEMS sensor as the first embodiment.

FIG. 3 is another top view of the MEMS sensor as the first embodiment.

FIG. 4 is another top view of a MEMS sensor.

FIGS. 5A through 5E are top views of a MEMS sensor as a second embodiment of the present invention.

FIGS. 6A and 6B are top views of a MEMS sensor as a third embodiment of the present invention.

FIGS. 7A and 7B are top views of a MEMS sensor as a fourth embodiment of the present invention.

FIGS. 8A through 8C are top views of a MEMS sensor as a fifth embodiment of the present invention.

FIGS. 9A through 9C are top views of a MEMS sensor as a sixth embodiment of the present invention.

FIG. 10 is an illustration depicting temperature characteristics.

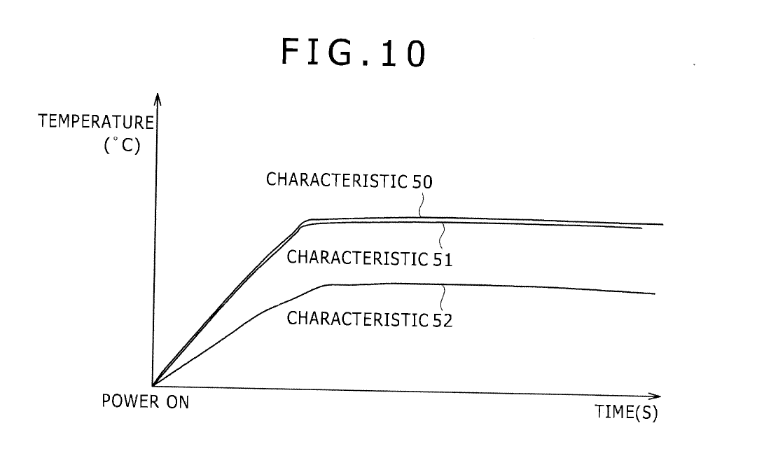

### MODES FOR CARRYING OUT THE INVENTION

The location from which heat is mostly generated when the signal processing LSI performs its signal processing operations can be known beforehand using simulation technology or the like. Given that knowledge, the present invention proposes positioning the MEMS sensor chip immediately over the heat generating part of the signal processing LSI and adjusting the positional relationship therebetween in such a manner that the temperature gradient of the MEMS sensor element as a whole is minimized and sensor performance is improved accordingly.

### First Embodiment

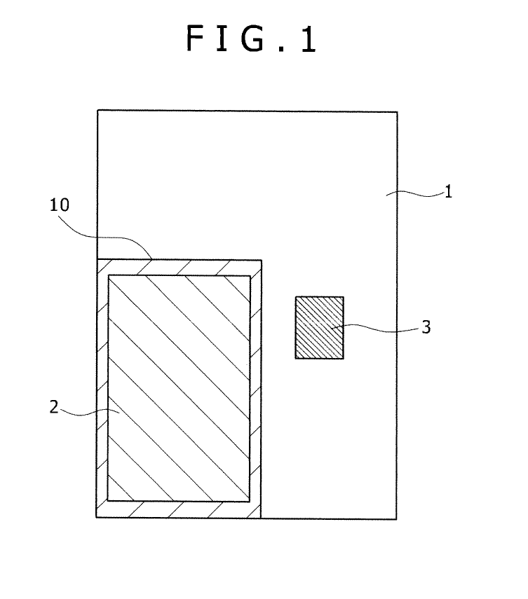

An embodiment of the present invention (first embodiment) is explained below using FIGS. 1 through 4.

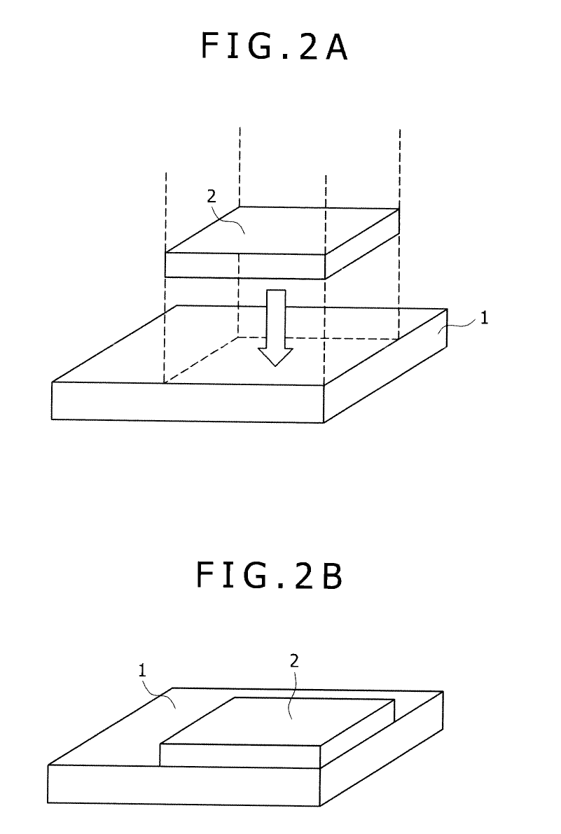

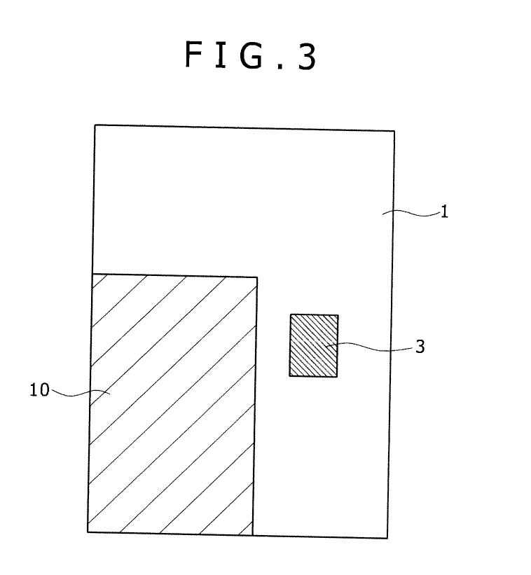

In FIG. 1, reference numeral 1 stands for a signal processing LSI, 2 for a MEMS sensor chip, 3 for a temperature measuring part, and 10 for a heat generating part of the signal processing LSI 1. Described below is the case where the heating generating part 10 and the temperature measuring part 3 are positioned relative to the signal processing LSI 1 as shown in FIG. 3A. This sensor has the MEMS sensor chip 2 overlaid on the signal processing LSI 1 as depicted in FIG. 2A, and the components are bonded together using an adhesive member (not shown) as indicated in the perspective view of FIG. 2B.

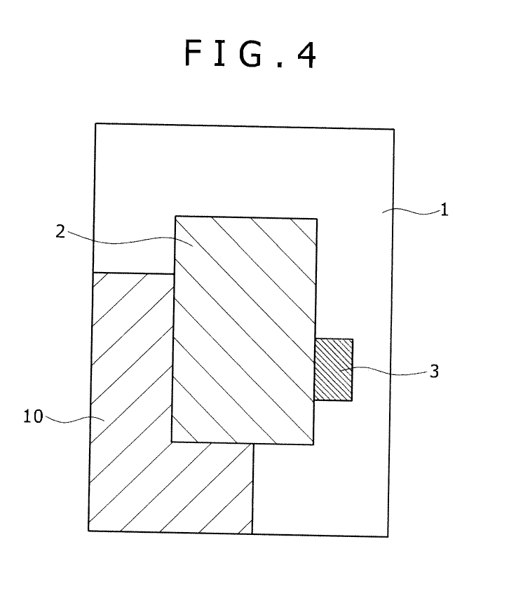

If the MEMS sensor chip 2 is positioned anywhere over the signal processing LSI 1 as shown in FIG. 4, part of the MEMS sensor chip 2 is heated by the heat generating part 10. This causes thermal heterogeneity on the MEMS sensor chip 2 leading to a temperature gradient thereon that brings about thermal unevenness in the sensor element. As a result, there is a fear that measurement accuracy may degrade particularly when the detection method involves measuring a difference between components. Thus the heat generating part 10 of the signal processing LSI 1 and the sensor chip 2 are configured so that the sensor chip 2 comes immediately over the heating part 10 as depicted in FIG. 1. This helps reduce the temperature gradient in the sensor element.

Also, the heat generating part 10 of the signal processing LSI 1 and the temperature measuring part 3 are positioned relative to each other as indicated in FIG. 1 so that the temperature measuring part 3 is not adjacent to the heat generating part 10. Rather, the components are laid out so that the position of the temperature measuring part 3 will bear the same thermal resistance and thermal capacity or the same proportions thereof as the thermal resistance between the heat generating part 10 of the signal processing LSI 1 and the MEMS sensor chip 2 and the thermal capacity possessed by the signal processing LSI 1 and sensor chip 2.

Given the above-described structure, it is possible to reduce the temperature gradient on the MEMS sensor chip 2 and correct transient temperature characteristics so that the effects caused by thermally triggered changes in temperature characteristics may be decreased.

### Second Embodiment

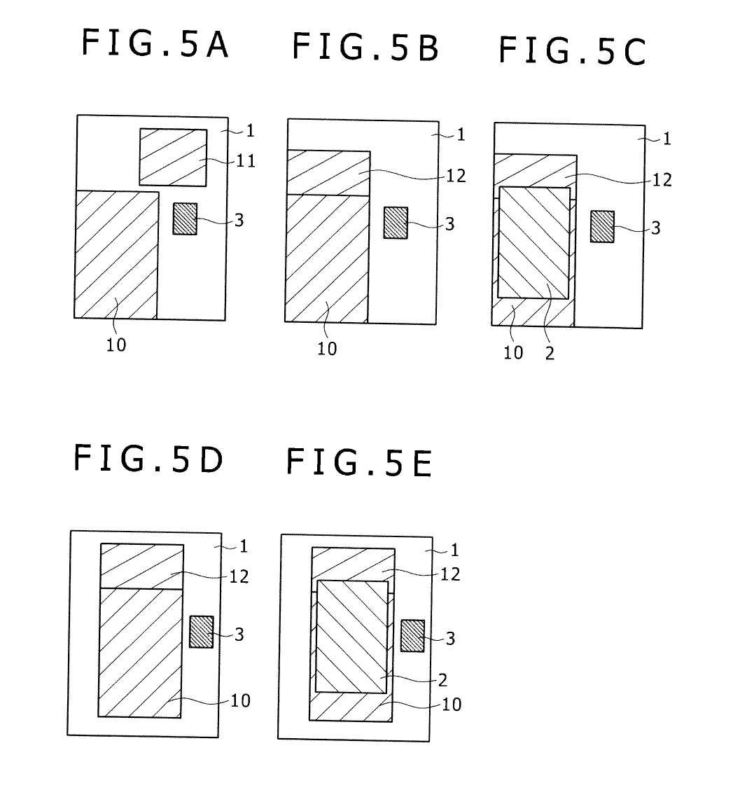

Another embodiment of the present invention (second embodiment) is explained next using FIG. 5. The same components as those in FIGS. 1 through 4 are designated by the same reference numerals, and their explanations are omitted.

It is assumed that the heat generating part 10 and another heat generating part 11 are located over the signal processing LSI 1 as depicted in FIG. 5A. In this case, the other heat generating part 11 may be relocated close to the heat generating part 10 to constitute another heating part 12 in the semiconductor layout as shown in FIG. 5B. The MEMS sensor chip 2 may then be positioned immediately over the heat generating part 10 and the other heating generating part 12 as indicated in FIG. 5C.

Also, the heat generating part 10 and the other heat generating part 11 in FIG. 5A may be rearranged as shown in FIG. 5D, with the heat generating part 11 reconfigured to make up another heat generating part 12. The heat generating parts are thus converged on the central location of the signal processing LSI 1, over which the MEMS sensor chip 2 may be overlaid as depicted in FIG. 5E.

When the temperature gradient in the sensor element on the MEMS sensor chip is reduced in this manner, the effects caused by thermally triggered changes in temperature characteristics can be decreased.

### Third Embodiment

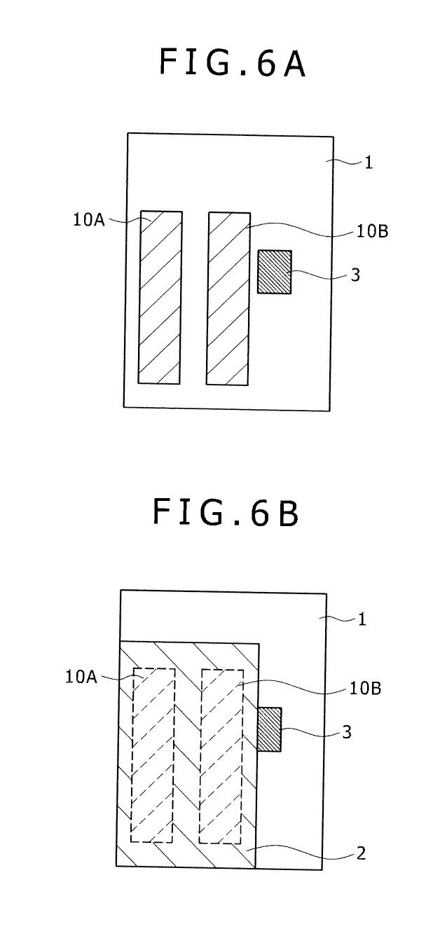

A further embodiment of the present invention (third embodiment) is explained next using FIG. 6. The same components as those in FIGS. 1 through 5 are designated by the same reference numerals, and their explanations are omitted.

This embodiment is explained using the case where the heat generating part 10 of the signal processing LSI 1 is smaller in size than the MEMS sensor chip 2.

A small-sized heat generating part 10 of the signal processing LSI 1 constitutes a small area for heat generation, often producing a temperature gradient in the sensor element on the MEMS sensor chip 2 through heat transmission. Thus the heat generating part 10 is divided as shown in FIG. 6A into a plurality of portions (2 portions for example with this embodiment) that are laid out to discourage formation of a temperature gradient in the sensor element on the MEMS sensor chip 2, as illustrated in FIG. 6B.

Even where the heat generating part 10 of the signal processing LSI 1 is smaller than the MEMS sensor chip 2, the above-described structure helps reduce the temperature gradient in the sensor element on the MEMS sensor chip and decrease the effects caused by thermally triggered changes in temperature characteristics.

### Fourth Embodiment

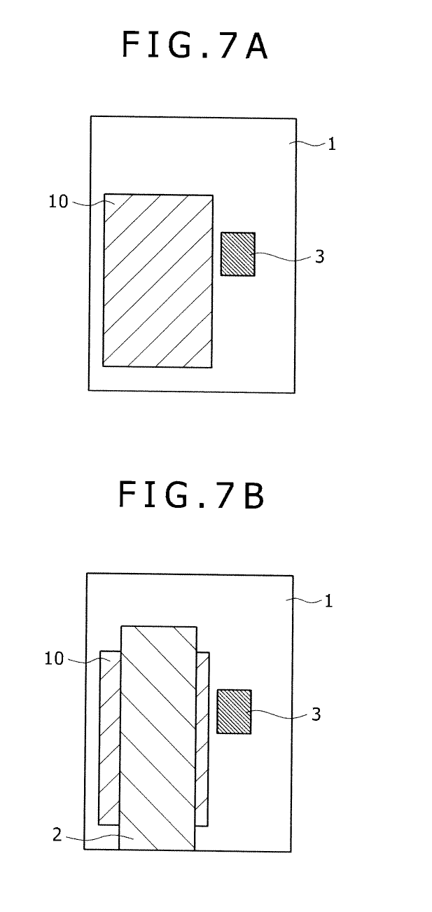

An even further embodiment of the present invention (fourth embodiment) is explained next using FIG. 7. The same components as those in FIGS. 1 through 6 are designated by the same reference numerals, and their explanations are omitted.

This embodiment is explained using the case where the heat generating part 10 of the signal processing LSI 1 differs considerably in shape from the MEMS sensor chip 2.

Suppose that the heat generating part 10 of the signal processing LSI 1 is shaped as depicted in FIG. 7A. It is also assumed that the MEMS sensor chip 2 has a long shape compared to the heat generating part 10 as shown in FIG. 7B. With this embodiment, the MEMS sensor chip 2 is laid out as indicated in FIG. 7B so that the temperature gradient in the sensor element on the MEMS sensor chip 2 is minimized.

Even where the heat generating part 10 of the signal processing LSI 1 differs greatly in shape from the MEMS sensor chip 2, the above-described structure helps reduce the temperature gradient in the sensor element on the MEMS sensor chip and decrease the effects caused by thermally triggered changes in temperature characteristics.

### Fifth Embodiment

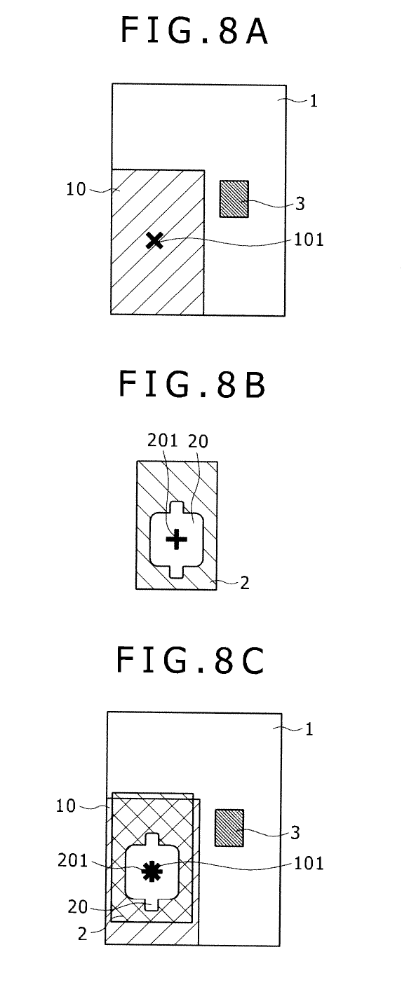

A still further embodiment of the present invention (fifth embodiment) is explained next using FIG. 8. The same components as those in FIGS. 1 through 7 are designated by the same reference numerals, and their explanations are omitted.

With this embodiment, it is assumed that the heat generating part 10 and the temperature measuring part 3 are laid out over the signal processing LSI 1 as shown in FIG. 8A. The calorific values from the heat generating part 10 are integrated per unit time. Reference numeral 101 denotes the center of the heat generating part calculated from the integrated values and from the area of the heat generating part. Meanwhile, FIG. 8B shows an example in which a single MEMS sensor element 20 is mounted on the MEMS sensor chip 2. It is assumed that with the MEMS sensor element 20 positioned on the MEMS sensor chip 2, a center 201 of that MEMS sensor element 20 is calculated from the area of the sensor part thereof as depicted in FIG. 8B.

In that case, the components are arranged so that the center 101 of the heat generating part 10 will coincide with the center 201 of the MEMS sensor element 20 as illustrated in FIG. 8C. This layout allows the heat transmitted from the heat generating part 10 of the signal processing LSI 1 to conduct in a relatively uniform manner to the sensor part of the MEMS sensor element 20 on the MEMS sensor chip 2, whereby the characteristics are stabilized.

Meanwhile, the temperature detecting part 3 on the signal processing LSI 1 measures the temperature of the heat transmitted from the heat generating part 10 over the signal processing LSI 1. If the temperature of the sensor part of the MEMS sensor element 20 is assumed to take on a characteristic 50 over time, the semiconductor process layout is arranged in terms of thermal resistance and thermal capacity so that the temperature detected by the temperature detecting part 3 will take on a characteristic 51. Alternatively, the semiconductor process layout is arranged so that a characteristic 52 will appear in proportion to the characteristic 50.

The above-described structure helps decrease the effects caused by thermally triggered changes in temperature characteristics.

### Sixth Embodiment

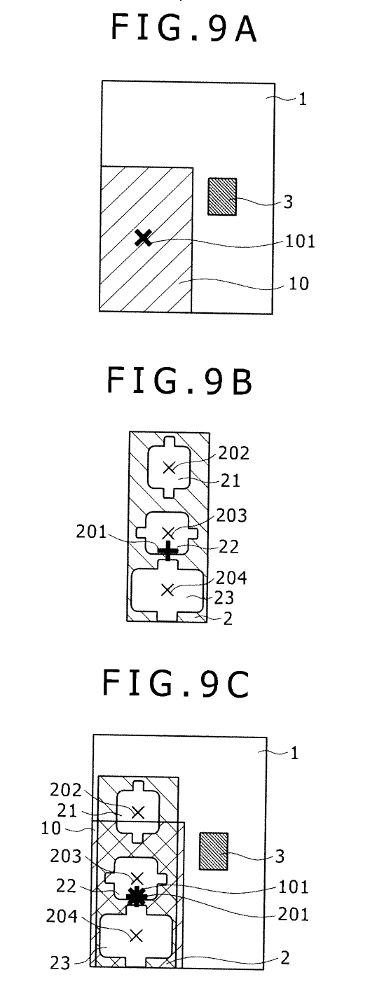

A yet further embodiment of the present invention (sixth embodiment) is explained next using FIG. 9. The same components as those in FIGS. 1 through 8 are designated by the same reference numerals, and their explanations are omitted.

With this embodiment, it is assumed that the heat generating part 10 and the temperature measuring part 3 are laid out over the signal processing LSI 1 as shown in FIG. 9A. The calorific values from the heat generating part 10 are integrated per unit time. Reference numeral 101 denotes the center of the heat generating part calculated from the integrated values and from the area of the heat generating part. Meanwhile, FIG. 9B shows an example in which a plurality of MEMS sensor elements (3 with this embodiment) are mounted on the MEMS sensor chip 2. It is assumed that with the MEMS sensor elements 21, 22 and 23 positioned on the MEMS sensor chip 2 as depicted in FIG. 9B, respective centers 202, 203 and 204 of these MEMS sensor elements are calculated from the area of each of their sensor parts as in the case of the fifth embodiment. A center 201 of these sensor parts is calculated from their overall areas.

In that case, the components are arranged so that the center 101 of the heat generating part 10 will coincide with the center 201 calculated from the MEMS sensor elements 21, 22 and 23 as illustrated in FIG. 9C. This layout allows the heat transmitted from the heat generating part 10 of the signal processing LSI 1 to conduct in a relatively uniform manner to the sensor parts of the MEMS sensor elements 21, 22 and 23 on the MEMS sensor chip 2, whereby the characteristics are stabilized.

Meanwhile, the temperature detecting part 3 on the signal processing LSI 1 measures the temperature of the heat transmitted from the heat generating part 10 over the signal processing LSI 1. If the temperature of the sensor parts of the MEMS sensor elements 21, 22 and 23 is assumed to take on the characteristic 50 over time, the semiconductor process layout is arranged in terms of thermal resistance and thermal capacity so that the temperature detected by the temperature detecting part 3 will take on the characteristic 51. Alternatively, the semiconductor process layout is arranged so that the characteristic 52 will appear in proportion to the characteristic 50.

Although typical MEMS sensors practiced as the above embodiments of the present invention are sensors that detect such externally applied signals as those of acceleration and angular velocity, these sensors are not limitative of this invention. The present invention may also be applied to other sensors such as a MEMS sensor integrating an acceleration sensor with an angular velocity sensor, a MEMS sensor integrating a biaxial acceleration sensor with an angular velocity sensor, and a MEMS sensor integrating a triaxial acceleration sensor with an angular velocity sensor.

### EXPLANATION OF LETTERS OR NUMERALS

1: Signal processing LSI
2: MEMS sensor chip
3: Temperature detecting part
10, 11, 12: Heat generating part
20, 21, 22, 23: MEMS sensor element
101: Center of the heat generating part
201, 202, 203, 204: Centers of MEMS sensor elements

This patent application incorporates all above-cited publications, patents, and patent applications by reference.

1. A MEMS sensor comprising:
a signal processing LSI equipped with a temperature sensor for measuring temperature of a sensor; and
a MEMS sensor chip overlaid on said signal processing LSI, wherein
said MEMS sensor chip is mounted on a heat generating part of said signal processing LSI.

2. A MEMS sensor according to claim 1, wherein
said MEMS sensor chip is an acceleration sensor.

3. A MEMS sensor according to claim 1, wherein
said MEMS sensor chip is an angular velocity sensor.

4. A MEMS sensor according to claim 1, wherein
said MEMS sensor chip is made up of an acceleration sensor and an angular velocity sensor.

5. A MEMS sensor according to claim 1, wherein
said MEMS sensor chip is made up of a biaxial acceleration sensor and an angular velocity sensor.

6. A MEMS sensor according to claim 1, wherein
said MEMS sensor chip is made up of a triaxial acceleration sensor and an angular velocity sensor.

7. A MEMS sensor according to claim 1, wherein
said temperature sensor is disposed on the position that bears thermal resistance and thermal capacity equivalent to the thermal resistance and thermal capacity in effect between the heat generating part of said signal processing LSI and a sensing part of said MEMS sensor.

8. A MEMS sensor according to claim 1, wherein
said temperature sensor is disposed on the position that bears thermal resistance and thermal capacity with the same proportions as those of the thermal resistance and thermal capacity in effect between the heat generating part of said signal processing LSI and a sensing part of said MEMS sensor.
